(19) United States
(12) Patent Application Publication
(10) Pub. No.: US 2017/0226660 A1
(43) Pub. Date: Aug. 10, 2017

(54) SEED CHUCK AND INGOT GROWING APPARATUS INCLUDING SAME

(71) Applicant: LG SILTRON INC., Gumi-si, Gyeongsangbuk-do (KR)

(72) Inventors: Jong-Min Kang, Gumi-si (KR); Tae-Sik Noh, Gumi-si (KR)

(21) Appl. No.: 15/502,148

(22) PCT Filed: Jul. 28, 2015
(86) PCT No.: PCT/KR2015/007856

§ 371 Date: Feb. 6, 2017

(30) Foreign Application Priority Data
Aug. 4, 2014 (KR) 10-2014-0099896

(51) Int. Cl. C30B 15/32; C30B 29/06; C30B 15/20

(52) U.S. Cl. CPC C30B 15/32; C30B 15/20; C30B 29/06

(57) ABSTRACT

The present invention relates to a seed chuck accommodating seed crystal so as to grow ingots in molten silicon, comprising: a neck cover for blocking thermal emission in the upward direction of the molten silicon; and a fixing part arranged on a bottom surface of the neck cover and accommodating the seed crystal, wherein the neck cover comprises: a top surface connected to a lifting cable; the bottom surface; and a circumferential surface connecting the top surface and the bottom surface, the circumferential surface is formed with an inclination angle with respect to the bottom surface, and a measurement part for measuring the molten silicon is opened in the neck cover such that the neck cover is positioned on the hole of an upper insulator so as to minimize heat loss through the hole of the upper insulator during a melting step and does not interfere in the temperature measurement of the molten silicon, thereby helping the temperature measurement of the molten silicon and increasing the reliability of molten silicon temperature sensing.

### TECHNICAL FIELD

The present invention relates to a seed chuck for production of a silicon ingot and ingot growing apparatus including the same.

### BACKGROUND ART

The silicon wafers are manufactured using silicon single crystalline ingots grown by a Czochralski (CZ) process (hereinafter, referred to as a CZ process) according to a large-scale diameter of a silicon wafer for production of semiconductor devices.

In the CZ process, polysilicon is put into a quartz crucible, the quartz crucible is heated by a graphite crucible to melt the polysilicon, a seed crystal is brought into contact with the molten silicon, and the seed crystal is rotated and pulled up so that crystallization occurs at the interface therebetween and a silicon single crystalline ingot having a desired diameter can be grown.

When the ingot is grown during the CZ process, heat is discharged to an upper side of the quartz crucible. When an amount of the discharged heat is excessive, since heat loss and power loss are increased and excessive heat is applied to the graphite crucible, lifetime of the graphite crucible and so on can be shortened and a cost of the ingot is increased.

Meanwhile, when the seed crystal is deeply dipped in the molten silicon, a temperature of a bottom of the seed crystal rapidly rises to a surface temperature of the molten silicon and a thermal shock is applied thereto. This thermal shock causes a shear stress, dislocation occurs at a portion of the seed crystal, which is in contact with the molten silicon, and thus quality of an ingot can be degraded.

### DISCLOSURE

### Technical Problem

The present invention is directed to providing a seed chuck capable of efficiently insulating a hot zone structure with a simple structure and measuring a temperature of molten silicon, and an ingot growing apparatus including the same.

### Technical Solution

One aspect of the present invention provides a seed chuck configured to accommodate a seed crystal for growing an ingot from molten silicon, the seed chuck including: a neck cover configured to block heat from being discharged in an upward direction of the molten silicon; and a fixing part disposed on a bottom surface of the neck cover and configured to accommodate the seed crystal, wherein the neck cover includes a top surface connected to a lifting cable, the bottom surface, and a circumferential surface configured to connect the top surface to the bottom surface, the circumferential surface is formed to have an inclination angle with respect to the bottom surface; and the neck cover has a measurement part which is open for measuring the molten silicon.

The inclination angle may be in a range of 39° to 48°.

The seed chuck may include an upper body including the top surface of the neck cover, a central body including the circumferential surface of the neck cover, and a lower body including the bottom surface of the neck cover, wherein the upper body is detachably coupled to the central body, and the a central body is detachably coupled to the lower body.

The neck cover may have a conical shape or a truncated conical shape.

An empty space may be formed inside the neck cover.

Another aspect of the present invention provides an ingot growing apparatus including: a chamber; a hot zone structure disposed inside the chamber and configured to accommodate silicon; a heater configured to heat the hot zone structure; an outer insulator positioned outside the hot zone structure; an upper insulator positioned above the hot zone structure and having a hole through which an ingot passes; a seed chuck configured to accommodate a seed crystal for growing the ingot from molten silicon; and a temperature sensor disposed above the chamber, wherein the seed chuck includes a neck cover configured to selectively block the hole, and a fixing part configured to accommodate the seed crystal, wherein the neck cover has a measurement part which is open so that the temperature sensor measures the molten silicon.

The temperature sensor may measure the molten silicon from an upper side of the neck cover through the measurement part.

The ingot growing apparatus may further include a controller configured to calculate a temperature of the molten silicon on the basis of data measured by the temperature sensor, wherein the controller may extract a maximum value among data of the temperature sensor, which is measured during a measurement cycle, to calculate the temperature of the molten silicon.

The neck cover may include an upper body including a cable connecting part connected to a lifting cable; a lower body including a bottom surface configured to face the molten silicon; and a central body including the bottom surface and a sloped circumferential surface.

Each of the central body and the lower body may have the measurement part which is open.

The central body may be detachably coupled to at least one of the upper body and the lower body.

The measurement part may be a measurement hole formed in an arc shape along an outer circumference of the neck cover.

A plurality of measurement holes, each of which is identical to the measurement hole, may be formed in the neck cover, and the neck cover may include a bridge located between the plurality of measurement holes.

The neck cover may include a circumferential surface configured to guide a fluid and a bottom surface configured to face the molten silicon, wherein the circumferential surface has an inclination angle with respect to the bottom surface, and the inclination angle is in a range of 39° to 48°.

The neck cover may further include a top surface which is parallel to the bottom surface.

### Advantageous Effects

The present invention is advantageous in that a neck cover can be positioned at a hole of an upper insulating body to minimize heat loss through the hole of the upper insulating body during a melting process, and heater power can be reduced with a simple structure.

In addition, there is an advantage that a neck cover can help temperature measurement of molten silicon without interfering with the temperature measurement of the molten silicon, thereby enhancing reliability of a detected temperature of the molten silicon.

Further, since a neck cover does not interfere with temperature measurement of molten silicon, there is an advantage in that it is possible to arrange the neck cover having an optimum size for improving heat insulating performance of a hot zone structure, and a degree of freedom in designing the neck cover can be increased.

Further, degradation of a hot zone structure can be minimized, and an amount of power can be reduced to reduce a production cost of an ingot.

Furthermore, since a neck cover can raise a temperature of an upper side of molten silicon together with an upper insulating body and a seed crystal located above the molten silicon can be deeply dipped in the molten silicon after being heated above the molten silicon, a thermal shock which can occur when the seed crystal is deeply dipped in the molten silicon, and quality of an ingot can be improved.

### DESCRIPTION OF DRAWINGS

FIG. 1 is a view illustrating an ingot growing apparatus according to an embodiment.

FIG. 2 is an enlarged view illustrating a seed chuck and an upper insulator according to the embodiment.

FIG. 3 is a graph illustrating a change in power of a heater according to an inclination angle of a neck cover.

FIG. 4 is a graph illustrating a change in power of a heater according to an outer diameter of a bottom surface of the neck cover.

FIG. 5 is an exploded perspective view illustrating a seed chuck according to a first embodiment.

FIG. 6 is a bottom view of a neck cover according to the first embodiment.

FIG. 7 is a graph illustrating data of a temperature sensor measured through the neck cover according to the first embodiment.

FIG. 8 is a view illustrating a process of measuring a temperature through the neck cover according to the first embodiment.

FIG. 9 shows graphs illustrating power and amounts of power when compared before and after the first embodiment is applied.

FIG. 10 is a bottom view of a neck cover according to a second embodiment.

FIG. 11 is a bottom view of a neck cover according to a third embodiment.

### MODES OF THE INVENTION

Hereinafter, the present embodiments will be described in detail with reference to the accompanying drawings. However, the scope of the embodiments of the present embodiment may be determined from the matters disclosed in the embodiments, and the spirit of the present invention possessed by the embodiments includes practical modifications such as addition, deletion, modification, and the like of components to the following proposed embodiment.

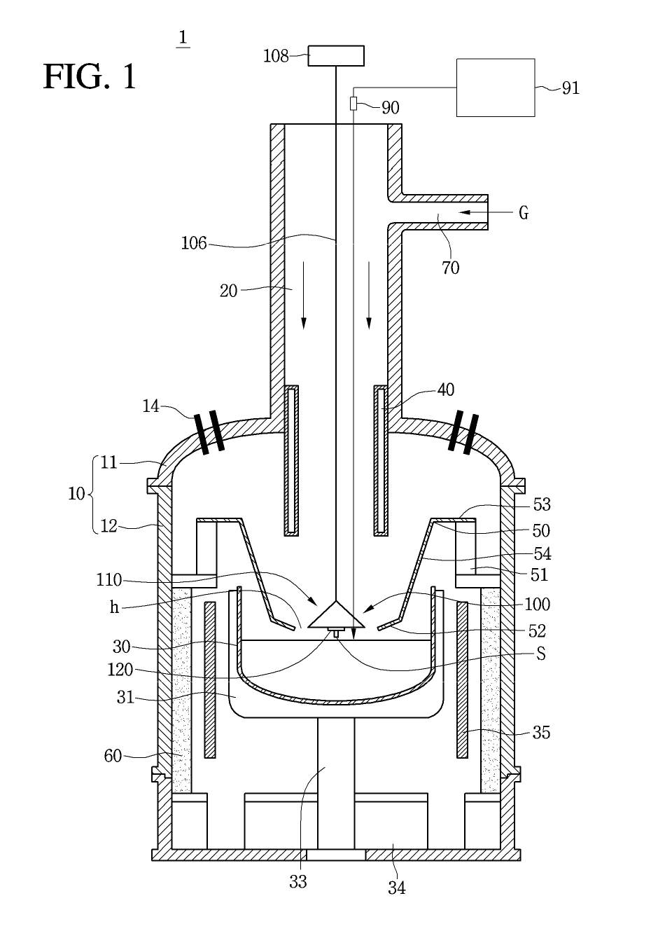

FIG. 1 is a view illustrating an ingot growing apparatus according to an embodiment.

Referring to FIG. 1, an ingot growing apparatus 1 may include a chamber 10, hot zone structures 30 and 31 disposed inside the chamber 10 and configured to accommodate silicon, a heater 35 configured to heat the hot zone structures 30 and 31, an outer insulator 60 positioned outside the hot zone structures 30 and 31, an upper insulator 50 positioned above the hot zone structures 30 and 31 and having a hole h through which an ingot passes, and a seed chuck 100 configured to accommodate a seed crystal for growing the ingot from molten silicon.

The chamber 10 may be provided with a space for growing the ingot.

The chamber 10 may include an upper chamber 11 and a lower chamber 12.

The upper chamber 11 may cover an upper portion of the lower chamber 12. A passage part 20 through which the ingot passes may be formed in the upper chamber 11. The passage part 20 may be formed to be long in a vertical direction in an upper portion of the upper chamber 11.

The lower chamber 12 may be coupled to the upper chamber 11. A space in which the hot zone structures 30 and 31, the heater 35, the outer insulator 60, and the upper insulator 50 are accommodated may be formed in the lower chamber 12.

The ingot growing apparatus 1 may include a hole for observing an inside of the chamber 10, which passes through the chamber 10, and may also further include a view port 14 for maintaining a sealing state of the chamber 10.

The hot zone structures 30 and 31 may include a quartz crucible 30 capable of accommodating silicon. The hot zone structures 30 and 31 may further include a graphite crucible 31 for accommodating the quartz crucible 30. The quartz crucible 30 is formed of quartz and formed in a bowl shape, and polysilicon may be accommodated in an internal space of the quartz crucible 30. The quartz crucible 30 is positioned at an inner side of the graphite crucible 31 to be supported by the graphite crucible 31.

The ingot growing apparatus 1 may further include a holder 33 configured to support the graphite crucible 31 and a crucible rotating part 34 which supports the holder 33 and may rotate and vertically move the holder 33. The crucible rotating part 34 simultaneously rotates the graphite crucible 31 in a direction opposite a rotational direction of the seed chuck 100 and lifts the graphite crucible 31 when the seed chuck 100 rotates.

The heater 35 may be installed to heat the hot zone structures 30 and 31. The heater 35 may be disposed to surround an outer side of the graphite crucible 31. The heater 35 may heat the graphite crucible 31 to melt polysilicon accommodated in the quartz crucible 30. The heater 35 may heat the graphite crucible 31, and the graphite crucible 31 being heated by the heater 35 may heat the quartz crucible 30.

The ingot growing apparatus 1 may further include a cooling pipe 40 for cooling the ingot. The cooling pipe 40 may be disposed inside the chamber 10, and the ingot may be cooled by passing through the cooling pipe 40. A part of the cooling pipe 40 may be disposed to be positioned at the passage part 20. A lower portion of the cooling pipe 40 may be disposed to be positioned inside the lower chamber 12.

The upper insulator 50 may be positioned above the quartz crucible 30. The upper insulator 50 may be installed to be placed on an insulating supporter 51 included in the chamber 10. The upper insulator 50 may include a central part 52, an edge part 53, and a connecting part 54. The upper insulator 50 may be formed to have a shape having at least one bent line.

The central part 52 may be positioned inside the quartz crucible 30. The central part 52 may be formed under the connecting part 54 and formed in a thecal shape of which size is gradually decreased in a downward direction. A bottom surface of the central part 52 may face silicon.

The edge part 53 may be positioned outside the quartz crucible 30. The edge part 54 may be formed above the connecting part 54 and formed in a ring shape.

The connecting part 54 may be formed to connect the central part 52 to the edge part 53. The connecting part 54 may be formed in a thecal shape of which size is gradually decreased in a downward direction. The connecting part 54 may be formed to be larger than a neck cover 110.

The hole h of the upper insulator 50 may be formed for passing an ingot grown from molten silicon. The hole h of the upper insulator 50 may be formed to be larger than an ingot which will be manufactured. The hole h of the upper insulator 50 may be formed in the central part 52 of the upper insulator 50. The hole h of the upper insulator 50 may have a circular shape.

The upper insulator 50 and the outer insulator 60 may surround and insulate the hot zone structures 30 and 31 and the heater 30. The outer insulator 60 may be a heat insulating material which insulates heat from being discharged in a lateral direction of the hot zone structures 30 and 31, and the upper insulator 50 may be a heat insulating material which insulates heat from being discharged in an upward direction of the hot zone structures 30 and 31.

A lower portion of the upper insulator 50 may be disposed to be inserted into the quartz crucible 30. The upper insulator 50 may be installed so that a part of the connecting part 54 and the central part 52 are positioned inside the quartz crucible 30.

The outer insulator 60 may be disposed outside the heater 35. The outer insulator 60 may be disposed around an outer side of the heater 35. The outer insulator 60 may be disposed to be positioned between the heater 35 and the chamber 10. The outer insulator 60 may be formed in a hollow thecal shape.

The ingot growing apparatus 1 may further include an inert gas supplier 70 which supplies an inert gas G from an upper portion of the chamber 10 toward inside of the chamber 10. The inert gas supplier 70 may be formed to communicate with the passage part 20, the inert gas G may be supplied to the passage part 20 through the inert gas supplier 70, and the inert gas G may pass through the passage part 20 and then pass through the upper insulator 50.

The ingot growing apparatus 1 may further include a temperature sensor 90 for measuring molten silicon. The temperature sensor 90 may be disposed above the chamber 10. The temperature sensor 90 may be installed to measure the temperature of the molten silicon. The temperature sensor 90 may be a non-contact temperature sensor capable of measuring the temperature of the molten silicon at a position spaced apart from the molten silicon. The temperature sensor 90 may be an infrared ray sensor or ultraviolet ray sensor and may measure the temperature of the molten silicon in a state which is not in contact with the molten silicon which is a measurement target.

The seed chuck 100 may include the neck cover 110 configured to selectively block the hole h and a fixing part 120 configured to accommodate the seed crystal.

The neck cover 110 may be connected to a lifting cable 106. The neck cover 110 may be moved up and down by the lifting cable 106. The neck cover 110 may block the hole h of the upper insulator 50 when positioned at the hole h of the upper insulator 50, and may open the hole h of the upper insulator 50 when lifted above the hole h of the upper insulator 50.

The neck cover 110 may be formed to have a smaller size that the hole h of the upper insulator 50. The neck cover 110 may have a smaller size than the hole h and may block a part of the hole h when positioned at the hole h. The neck cover 110 may not block the entire hole h and may block only a part of the hole h when positioned at the hole h.

A degree of opening of the hole h may vary according to a lifting position of the neck cover 110, and an opening area of the hole h may be adjusted by a position of the neck cover 110.

When polysilicon is melting, a cable driver 108 may position the neck cover 110 at the hole h of the upper insulator 50, and heat from being discharged through the hole h may be minimized. That is, the neck cover 110 may minimize heat discharged through the hole h of the upper insulator 50, and heat discharged in an upward direction from the quartz crucible 30 may be minimized by the upper insulator 50 and the neck cover 110.

When the neck cover 110 is not provided at the hole h of the upper insulator 50, heat loss through the hole h of the upper insulator 50 may be great. Heat generated in process of melting polysilicon to be molten silicon may be discharged in an upward direction of the hole h of the upper insulator 50 through the hole h of the upper insulator 50, and when an amount of discharged heat is great, an overall melting process time may be long, power loss is great, and degradation of the hot zone structures 30 and 31 may be severe.

Otherwise, when the neck cover 110 is formed, heat from being excessively discharged through the hole h of the upper insulator 50 can be prevented because the neck cover 110 blocks a part of the hole h of the upper insulator 50.

Meanwhile, when the neck cover 110 may not block the part of the hole h and a seed crystal S is deeply dipped in molten silicon, a thermal shock on the seed crystal S may be great due to a temperature difference between the seed crystal S and the molten silicon and a dislocation of an ingot may occur.

Otherwise, when the neck cover 110 blocks the part of the hole h, a temperature in a space between the hole h and the molten silicon may be increased when compared with a case in which the neck cover 110 does not block the part of the hole h, a temperature of the seed crystal S is increased to be similar to that of the molten silicon in the space between the neck cover 110 and the molten silicon, and then the seed crystal S may be deeply dipped in the molten silicon. That is, the temperature difference between the seed crystal S and the molten silicon can be minimized, and the dislocation occurring in the ingot can be minimized.

The lifting cable 106 may rotate and move the seed chuck 100 up and down. The lifting cable 106 may rotate and move the neck cover 110 up and down, and the fixing part 120 disposed under the neck cover 110 may be rotated and moved up and down together with the neck cover 110.

The ingot growing apparatus may include the cable driver 108 configured to operate the lifting cable 106.

The cable driver 108 may be disposed to be positioned above the chamber 10. The lifting cable 106 may be wound around the cable driver 108. The cable driver 108 unwinds the lifting cable 106 so that the seed chuck 100 is moved downward to approach silicon, and in this case, the seed crystal S accommodated in the seed chuck 100 may be deeply dipped in molten silicon. The cable driver 108 may pull the lifting cable 106 and simultaneously rotate and lift the seed chuck 100 to grow an ingot.

The cable driver 108 may operate the lifting cable 105 so that the neck cover 110 is positioned at the hole h of the upper insulator 50 during a melting process.

The neck cover 110 may be a moving block being moved by the lifting cable 106 and may be a moving controller capable of adjusting an opening area of the hole h of the upper insulator 50.

The cable driver 108 may move the neck cover 110 up and down to an optimum position in consideration of insulation performance and the quality of the ingot.

The fixing part 120 may be disposed under the neck cover 110. The fixing part 120 may be positioned above the quartz crucible 30 and may accommodate the seed crystal S for growing an ingot from molten silicon. The fixing part 120 may be connected to the lifting cable 106 through the neck cover 110 and may also be directly connected to the lifting cable 106.

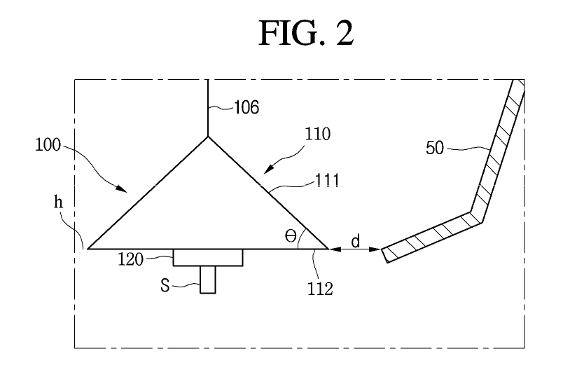

FIG. 2 is an enlarged view illustrating a seed chuck and an upper insulator according to the embodiment.

The neck cover 110 may include a circumferential surface 111 configured to guide a fluid and a bottom surface 112 facing molten silicon.

The neck cover 110 may be positioned at the hole h, and at this time, the circumferential surface 111 may guide a gas supplied through the inert gas supplier 70 shown in FIG. 1 to a space between the neck cover 110 and the upper insulator 50.

That is, the gas supplied through the inert gas supplier 70 shown in FIG. 1 is guided along the circumferential surface 111 and then flows to the space between the neck cover 110 and the upper insulator 50.

The circumferential surface 111 of the neck cover 110 may be formed to be sloped by a predetermined angle with respect to the bottom surface 112. An inert gas supplied through the inert gas supplier 70 may be guided along the sloped circumferential surface 111 of the neck cover 110, pass through the space between the neck cover 110 and the upper insulator 50, and then smoothly flows toward molten silicon. That is, the circumferential surface 111 may have an inclination angle θ with respect to the bottom surface 112.

Meanwhile, the neck cover 110 may have a shape corresponding to a shape of the hole h of the upper insulator 50. When the hole h of the upper insulator 50 has a circular shape, a diameter of the bottom surface 112 of the neck cover 110 may be smaller than a diameter of the hole h of the upper insulator 50. When the neck cover 110 is positioned at the hole h of the upper insulator 50, an outer circumference of the neck cover 110 and the upper insulator 50 may be spaced a separation distance d from each other. The neck cover 110 may not collide and interfere with the upper insulator 50.

When the hole h of the upper insulator 50 has a circular shape, the neck cover 110 may be formed in a conical shape or truncated conical shape and may block a part of the hole h of the neck cover 110. An empty space may be formed inside the neck cover 110.

The neck cover 110 may be formed of graphite. A pyrolytic carbon coating layer is formed on a bottom surface of the neck cover 110 to improve an insulation capability.

A temperature distribution around the hole when the neck cover 110 is positioned at the hole h of the upper insulator 50, a temperature distribution around the hole when the neck cover 110 is lifted a first height (e.g., 40 mm) from the hole h of the upper insulator 50, and a temperature distribution around the hole when the neck cover 110 is lifted by a second height (e.g., 80 mm) which is higher than the first height are different from each other.

Power of the heater 35 may be minimum when the neck cover 110 is positioned at the hole h of the upper insulator 50, and may be increased proportional to lifting of the neck cover 110 in an upward direction of the hole h of the upper insulator 50.

The power of the heater 35 may be determined by temperature measurement of the hot zone structures 30 and 31, a decrease in the power of the heater 35 may denote that temperatures of the hot zone structures 30 and 31 are sufficiently high by the neck cover 110, and a degree of the decrease in the power of the heater 35 may denote a degree of an insulation capability improved by the neck cover 110.

It is most preferable that the neck cover 110 be positioned at the hole h of the upper insulator 50 during a melting process for the ingot growing apparatus.

The fixing part 120 may be disposed on the bottom surface 112 of the neck cover 110. The fixing part 120 may be positioned to protrude from the bottom surface 112 of the neck cover 110. The fixing part 120A may have a receiving groove configured to accommodate the seed crystal S. Further, the receiving groove may have a fixing groove configured to solidly fix the seed crystal S. In addition, the fixing part 120 may be formed of graphite, and a pyrolytic carbon coating layer may be formed on the fixing part 120 to improve an insulation capability.

Meanwhile, a heat distribution around the neck cover 110 may vary according to the inclination angle θ of the neck cover 110.

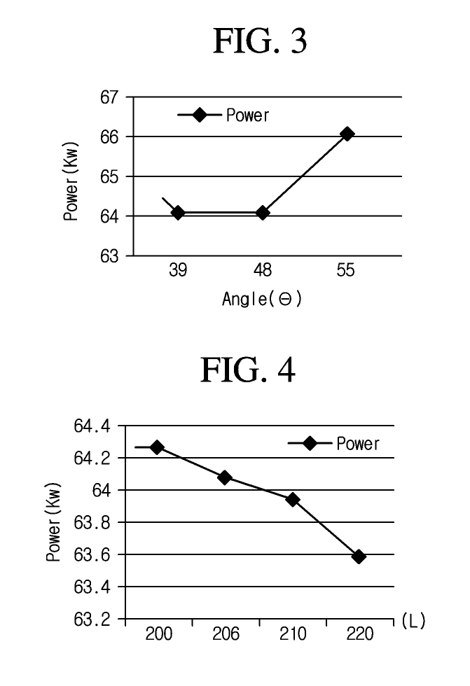

FIG. 3 is a graph illustrating a change in power of the heater 35 according to the inclination angle θ of the neck cover 110.

Referring to FIG. 3, it shows that, when the inclination angle θ of the neck cover 110 is lower than 39°, the power of the heater 35 is high because an insulation capability of the neck cover 110 is low, and when the inclination angle θ of the neck cover 110 is higher than 48°, the power of the heater 35 is rapidly increased because the insulation capability of the neck cover 110 is low. It is preferable that the inclination angle θ of the neck cover 110 be in a range of 39° to 48°.

FIG. 4 is a graph illustrating a change in power of a heater according to an outer diameter of a bottom surface of a neck cover.

Referring to FIG. 4, it shows that the power of the heater 35 is gradually decreased when an outer diameter of the neck cover 110 is 200 mm or less, and it is preferable that the outer diameter of the neck cover 110 be 200 mm or more, but the present invention is not limited thereto.

Meanwhile, when the outer diameter of the neck cover 110 is greater than a size of the hole h, the neck cover 110 may collide and interfere with the upper insulator 50, and it is preferable that the neck cover 110 be smaller than the hole h of the upper insulator 50.

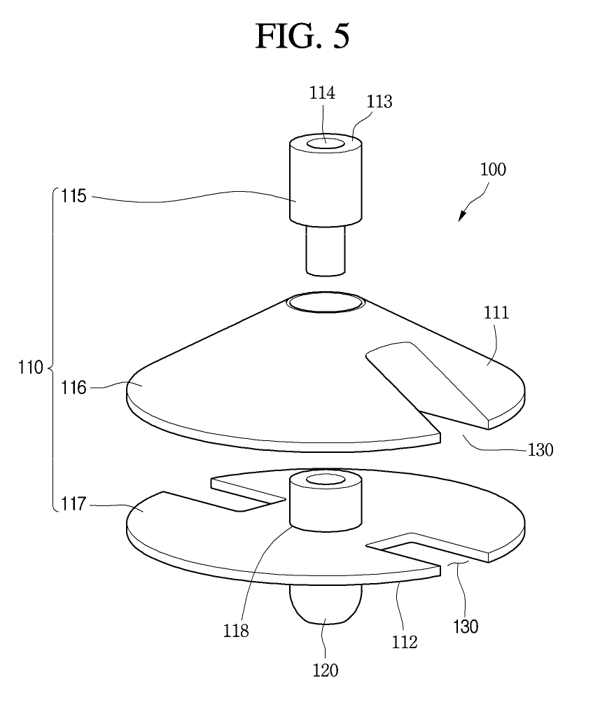

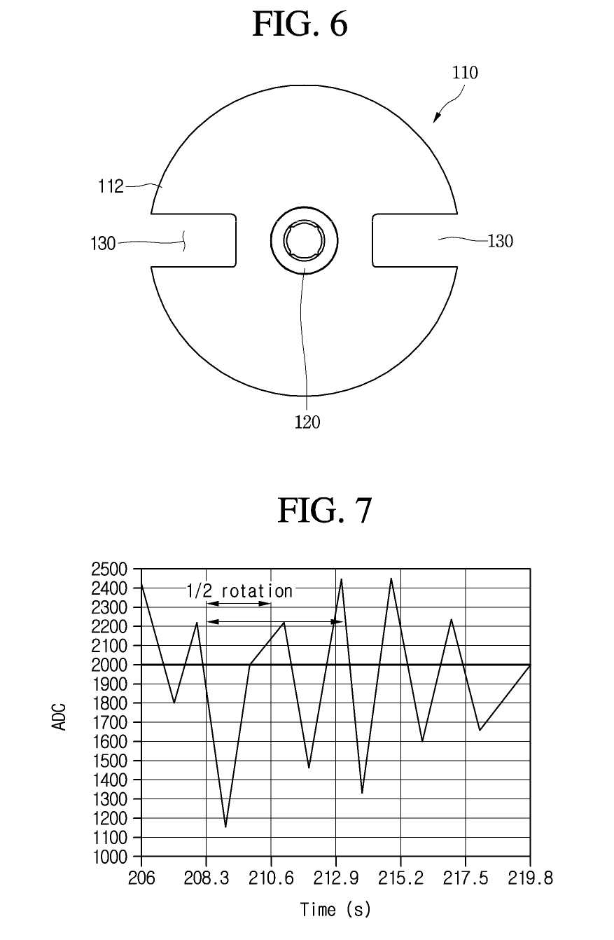

FIG. 5 is an exploded perspective view of a seed chuck according to a first embodiment, and FIG. 6 is a bottom view illustrating a neck cover according to the first embodiment.

Referring to FIG. 5, a neck cover 110 may further include a top surface 113 which is parallel to a bottom surface 112.

The neck cover 110 may include a circumferential surface 111, the bottom surface 112, and the top surface 113, and an entire shape may be a truncated conical shape.

The neck cover 110 may include a cable connecting part 114 connected to a lifting cable 106. The cable connecting part 114 may be included in an upper portion of the neck cover 110. The cable connecting part 114 may include a groove through which the lifting cable 106 is connected.

The neck cover 110 may include a coupler having a plurality of members, and each component may be formed detachably.

The neck cover 110 may include an upper body 115, a central body 116 including the circumferential surface 111, and a lower body 117 including the bottom surface 112.

Each of the upper body 115, the central body 116, and the lower body 117 may be formed to have a predetermined thickness, and an empty space may be formed inside the neck cover 110 when the upper body 115, the central body 116, and the lower body 117 are coupled to each other.

A top surface of the upper body 115 may be the top surface 113 of the neck cover 110, and the upper body 115 may include the cable connecting part 114.

The central body 116 may have a truncated conical shape of which a diameter is gradually increased in a downward direction.

The central body 116 may be detachably coupled to at least one of the upper body 115 and the lower body 117. A male screw may be formed on any one of the upper body 115 and the central body 116, a female screw to be coupled to the male screw may be formed on the other one thereof, and the upper body 115 is screw-coupled to the central body 116.

A male screw may be formed on any one of the central body 116 and the lower body 117, a female screw coupled to the male screw may be formed on the other one thereof, and the central body 116 may be screw-coupled to the lower body 117.

A fixing part through hole 118, through which the fixing part 120 passes and in which the fixing part 120 is disposed, may be formed in the lower body 117.

Meanwhile, the temperature sensor 90 shown in FIG. 1 may emit light toward molten silicon and measure a temperature of the molten silicon by sensing light reflected and received from the molten silicon.

A part of the neck cover 110 may be positioned between the temperature sensor 90 and the molten silicon, and the neck cover 110 may be formed so that the temperature sensor 90 measures the temperature of the molten silicon.

The neck cover 110 may have a measurement part 130 which is open for measuring the molten silicon. The neck cover 110 may have the measurement part 130 which is open so that the temperature sensor 90 may measure the molten silicon. The measurement part 130 is open at a position of the neck cover 110, which faces the temperature sensor 90. The measurement part 130 may be formed in the neck cover 110 in a groove shape or a hole shape.

The temperature sensor 90 may be an infrared ray sensor or ultraviolet ray sensor which may measure a temperature of the molten silicon from an upper side of the neck cover 110 through the measurement part 130. Light emitted by the temperature sensor 90 may emit to the molten silicon by passing through the measurement part 130, and the temperature of the molten silicon may be measured using light reflected from the molten silicon.

The temperature sensor 90 may determine brightness of the molten silicon, which is checked through the measurement part 130, to measure the temperature of the molten silicon.

Each of the central body 116 and the lower body 117 may have the measurement part 130 which is open. The measurement part 130 may include an opening groove formed on an outer circumference of the central body 116 and an opening groove formed on an outer circumference of the lower body 117.

Meanwhile, the neck cover 110 may be rotated, and when the neck cover 110 is rotated, the measurement part 130 may be positioned at a position which faces or does not face the temperature sensor 90.

Time points for measuring a temperature of the temperature sensor 90 may be classified as a time point for measuring the temperature of the molten silicon through the measurement part 130 and a time point for measuring a temperature of the neck cover 110. Data of the temperature of the molten silicon measured through the measurement part 130 and data of the temperature of the neck cover 110 may be mixed in data measured by the temperature sensor 90, and it is preferable to select only the data of the temperature of the molten silicon measured through the measurement part 130.

The ingot growing apparatus may further include the controller 91 (see FIG. 1) which may control each component. The controller 91 may calculate the temperature of the molten silicon according to the data measured by the temperature sensor 90.

The controller 91 may extract a maximum value among data of the temperature sensor 90 measured during a measurement cycle to calculate the temperature of the molten silicon.

The temperature sensor 90 may be connected to the controller 91, and the controller 91 may collect data measured by the temperature sensor 90 in real time so as to calculate the temperature of the molten silicon.

FIG. 7 is a graph illustrating data of a temperature sensor measured through the neck cover according to the first embodiment.

The neck cover 110 of the first embodiment is a case in which two measurement parts 130 are formed, and in this case, the neck cover 110 may measure temperatures of molten silicon using the measurement part 130 at two sections whenever the neck cover 110 rotates one time.

Referring to FIG. 7, it shows that the temperature ADC of the molten silicon measured by the temperature sensor 90 has a peak value and fluctuates over time. This is because a high temperature is calculated when the temperature of the molten silicon is measured through the measurement part 130 and a low temperature is calculated when a temperature of the neck cover 110 outside the measurement part 130 is measured.

The controller 91 may calculate a temperature of the molten silicon using a peak value among temperatures measured by the temperature sensor 90. The controller 91 may extract a temperature value of the molten silicon from data values measured by the temperature sensor 90 using a high-pass filter or a maximum value (Max) processor.

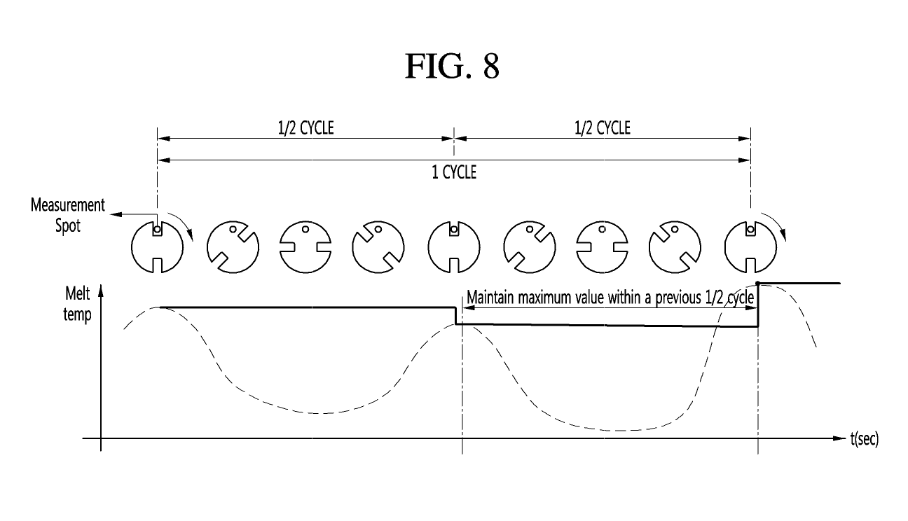

FIG. 8 is a view illustrating a process of measuring a temperature through the neck cover according to the first embodiment.

The ingot growing apparatus 1 may more precisely measure a temperature of molten silicon using the measurement part 130 of the neck cover 110. Referring to FIG. 8, even when a direction in or position at which the temperature sensor 90 is measured is constant, the temperature of the molten silicon may be measured and a temperature of the neck cover 110 may be measured according to the neck cover 110 being rotated.

A cycle for measuring an actual temperature of molten silicon using the temperature sensor 90 may be calculated by the following Equation.

$$T ( sec ) = 60 \times \frac{r}{n} \qquad [ Equation 1 ]$$

Here, T denotes a measurement cycle (seconds), r denotes seed chuck rotation (RPM), and n denotes the number of measurement parts.

In order to calculate the measurement cycle according to the number of the measurement parts 130, when the plurality of measurement parts 130 are formed, the measurement parts 130 may be formed to be spaced a predetermined distance from each other.

The controller 91 may measure a temperature of the molten silicon by extracting data in each measurement cycle from a measurement time point of the temperature of the molten silicon among data of the temperature sensor 90.

The controller 91 may calculate the temperature of the molten silicon in a measurement cycle section using a maximum temperature at a time point measured the temperature of the molten silicon. The controller 91 may output a maximum temperature after measured temperatures of the molten silicon as the temperature of the molten silicon in a measurement cycle. The controller 91 may remeasure a maximum temperature at a time point which passed the measurement cycle and output the maximum temperature as the temperature of the molten silicon in a next measurement cycle section. This is defined as a high-pass filter technique.

The controller 91 may accurately measure the temperature of the molten silicon using the high-pass filter technique.

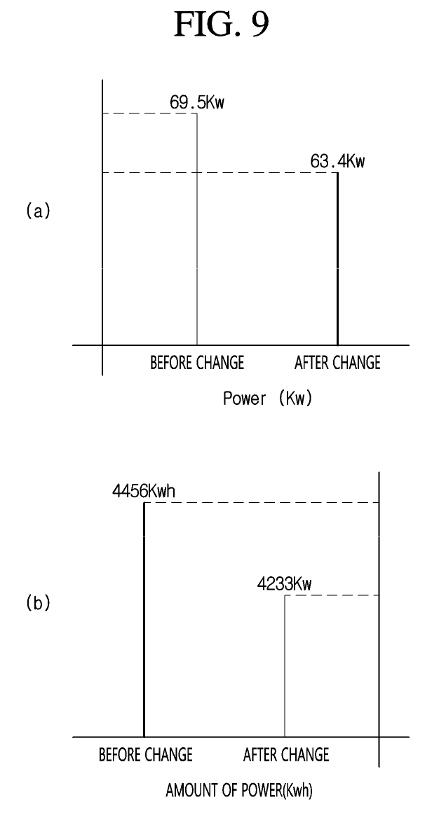

FIG. 9 shows graphs illustrating power (FIG. 9A) and amounts of power (FIG. 9B) when compared before and after the first embodiment is applied.

When a temperature of molten silicon is accurately measured through the measurement part 130, the controller 91 may accurately calculate power for adding to or removing from the heater 35, and accordingly, the heater 35 may be controlled.

The term “before change” illustrated in FIG. 9 denotes a case in which the neck cover 110 and the high-pass filter technique according to the present invention are not applied, and the term “after change” illustrated in FIG. 9 is a case in which the neck cover 110 and the high-pass filter technique according to the present invention are applied.

It shows that heat loss is reduced because the neck cover 110 is applied, and the power and the amount of power are reduced by accurately calculating the temperature of the molten silicon by the controller 91 using the high-pass filter technique.

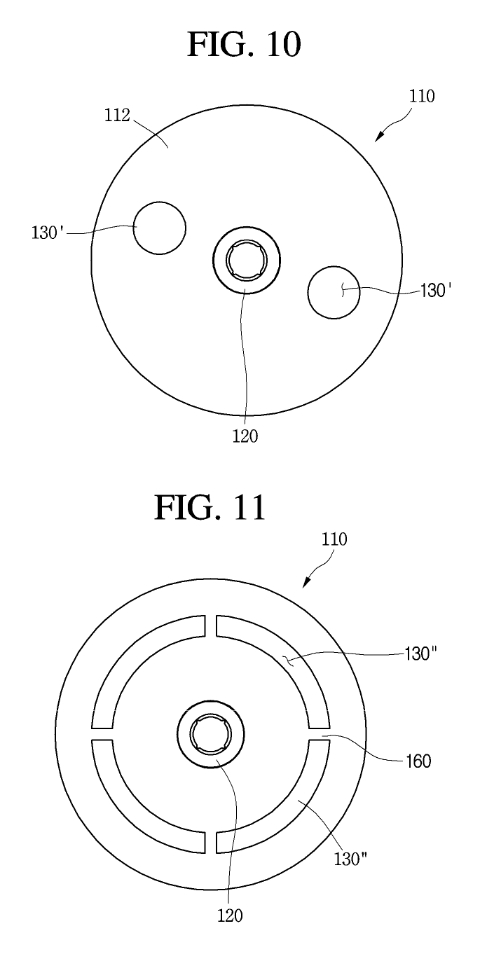

FIG. 10 is a bottom view of a neck cover according to a second embodiment.

A measurement part 130′ of a neck cover 110 according to the second embodiment has a different shape from the measurement part 130 of the neck cover 110 according to the first embodiment, and detailed descriptions of the same components as in the first embodiment will be omitted.

The neck cover 110 according to the second embodiment may have a hole shape such as a shape of the measurement part 130′. The measurement part 130′ according to the second embodiment may be formed in a hole shape at the central body 116 and the lower body 117, and formed to correspond to a position and size of a measurement spot of the temperature sensor 90.

The measurement part 130′ according to the second embodiment may have an opening area which is smaller than the measurement part 130 according to the first embodiment, and may more improve a degree of insulation of the neck cover 110.

FIG. 11 is a bottom view of a neck cover according to a third embodiment.

A neck cover 110 according to the third embodiment is modified from shapes of the measurement part 130 according to the first embodiment and the measurement part 130′ of the neck cover 110 according to the second embodiment, and detailed descriptions of the same components as in the first embodiment or in the second embodiment will be omitted.

A measurement part formed in the neck cover 110 according to the third embodiment may be at least one measurement hole 130″ formed in an arc shape along an outer circumference of the neck cover 110.

A plurality of measurement holes may be formed in the neck cover 110, and the neck cover 110 may include bridges 160 located between the plurality of measurement hole 130″.

The bridge 160 may be positioned between the pair of measurement holes 130″ to support a circumferential surface of the neck cover 110.

The temperature sensor 90 positioned above the chamber 10 may measure a temperature of molten silicon through the arc-shaped measurement hole 130″.

The third embodiment may allow that the temperature sensor 90 measures the temperature of the molten silicon except for the bridge 160, a time for detection of the temperature of the molten silicon may be longer than that of the second embodiment, and it is advantageous to measure the temperature of the molten silicon more accurately.

The features, structures, effects and the like described in the above embodiments are included in at least one embodiment and are not necessarily limited to only one embodiment. Further, the features, structures, effects, and the like illustrated in the embodiments may be combined and modified by those skilled in the art to which the embodiments belong. Accordingly, the contents of such combinations and modifications should be interpreted as being included in the scope of the embodiments.

While the present invention has been particularly shown and described with reference to exemplary embodiments thereof, it is to be understood that the present invention is not limited to the disclosed embodiments, but it will be understood by those skilled in the art that various changes and modifications may be made without departing from the spirit and scope of the present invention. For example, each component specifically shown in the embodiments may be modified and implemented. Further, it should be understood that such modifications and applications are to be construed as being included within the scope of the embodiments set forth in the appended claims.

### INDUSTRIAL APPLICABILITY

According to the present invention, since a neck cover can prevent heat from being discharged to an upper side of molten silicon and, at the same time, can help measurement of a temperature of the molten silicon, it is possible to produce a high quality ingot while minimizing energy and an industrial use value is high.

1. A seed chuck configured to accommodate a seed crystal for growing an ingot from molten silicon, the seed chuck comprising:
a neck cover configured to block heat from being discharged in an upward direction of the molten silicon; and
a fixing part disposed on a bottom surface of the neck cover and configured to accommodate the seed crystal,
wherein:
the neck cover includes a top surface connected to a lifting cable, the bottom surface, and a circumferential surface configured to connect the top surface to the bottom surface;
the circumferential surface is formed to have an inclination angle with respect to the bottom surface; and
the neck cover has a measurement part which is open for measuring the molten silicon.

2. The seed chuck of claim 1, wherein the inclination angle is in a range of 39° to 48°.

3. The seed chuck of claim 1, wherein the seed chuck includes:
an upper body including the top surface of the neck cover;
a central body including the circumferential surface of the neck cover; and
a lower body including the bottom surface of the neck cover,
wherein the upper body is detachably coupled to the central body, and the central body is detachably coupled to the lower body.

4. The seed chuck of claim 1, wherein the neck cover has a conical shape or a truncated conical shape.

5. The seed chuck of claim 1, wherein an empty space is formed inside the neck cover.

6. An ingot growing apparatus comprising:
a chamber;
a hot zone structure disposed inside the chamber and configured to accommodate silicon;
a heater configured to heat the hot zone structure;
an outer insulator positioned outside the hot zone structure;
an upper insulator positioned above the hot zone structure and having a hole through which an ingot passes;
a seed chuck configured to accommodate a seed crystal for growing the ingot from molten silicon; and
a temperature sensor disposed above the chamber,
wherein the seed chuck includes:
a neck cover configured to selectively block the hole; and
a fixing part configured to accommodate the seed crystal,
wherein the neck cover has a measurement part which is open so that the temperature sensor measures the molten silicon.

7. The ingot growing apparatus of claim 6, wherein the temperature sensor measures the molten silicon from an upper side of the neck cover through the measurement part.

8. The ingot growing apparatus of claim 6, further comprising a controller configured to calculate a temperature of the molten silicon on the basis of data measured by the temperature sensor,
wherein the controller extracts a maximum value among data of the temperature sensor, which is measured during a measurement cycle, and calculates the temperature of the molten silicon.

9. The ingot growing apparatus of claim 6, wherein the neck cover includes:
an upper body including a cable connecting part connected to a lifting cable;
a lower body including a bottom surface configured to face the molten silicon; and
a central body including the bottom surface and a sloped circumferential surface.

10. The ingot growing apparatus of claim 9, wherein each of the central body and the lower body has the measurement part which is open.

11. The ingot growing apparatus of claim 9, wherein the central body is detachably coupled to at least one of the upper body and the lower body.

12. The ingot growing apparatus of claim 6, wherein the measurement part is a measurement hole formed in an arc shape along an outer circumference of the neck cover.

13. The ingot growing apparatus of claim 12, wherein:
a plurality of measurement holes are formed in the neck cover; and
the neck cover includes a bridge located between the plurality of measurement holes.

14. The ingot growing apparatus of claim 6, wherein the neck cover includes:
a circumferential surface configured to guide a fluid; and
a bottom surface configured to face the molten silicon,
wherein the circumferential surface has an inclination angle with respect to the bottom surface, and the inclination angle is in a range of 39° to 48°.

15. The ingot growing apparatus of claim 14, wherein the neck cover further includes a top surface which is parallel to the bottom surface.
